(19) United States
(12) Patent Application Publication
(10) Pub. No.: US 2008/0014732 A1
(43) Pub. Date: Jan. 17, 2008

(54) Application of PVD W/WN bilayer barrier to aluminum bondpad in wire bonding

(76) Inventors: Yanping Li, Mountain View, CA (US); Lisa Yang, Saratoga, CA (US); Suraj Rengarajan, San Jose, CA (US)

Correspondence Address: PATTERSON & SHERIDAN, LLP, 3040 POST OAK BOULEVARD, SUITE 1500, HOUSTON, TX, 77056, US

(21) Appl. No.: 11/482,522

(22) Filed: Jul. 7, 2006

(51) Int. Cl. H01L 21/44

(52) U.S. Cl. 438/597

(57) ABSTRACT

An aluminum bondpad and method for making the aluminum bondpad is disclosed. In forming aluminum bondpads, a barrier layer is necessary between a copper interconnect layer and the aluminum bondpad layer. Additionally, a gold wiring layer is deposited on the aluminum bondpad layer and annealed at a high temperature to form an aluminum-gold intermetallic compound. Aluminum reacts with tungsten at high temperatures. Therefore, during the annealing, the aluminum will react with the tungsten. By providing a tungsten nitride barrier layer on a tungsten barrier layer, no aluminum-tungsten intermetallic compound will form, even at the high annealing temperatures required to form the aluminum bondpad.

### BACKGROUND OF THE INVENTION

1. Field of the Invention

Embodiments of the present invention generally relate to an aluminum bondpad structure and method for making the structure.

2. Description of the Related Art

Aluminum bondpads are a form of final level of interconnect structures that connect external wiring to semiconductor chips. Copper, in recent years, has become the widely used backend interconnect material. In the most common scheme of forming aluminum bondpads on the last level of copper interconnect pads, a barrier layer is necessary between the aluminum layer and the copper layer because the aluminum and the copper will interdiffuse and react to form a copper-aluminum intermetallic compound. Conventional barrier materials include tungsten, tantalum, titanium, and their nitrides. A gold wire layer is then bonded to the aluminum pad using thermal and mechanical energy. Finally, the wire-bonded chip is annealed so that the aluminum and gold will at least partially react and form a strong bond joint consisting of aluminum-gold intermetallic compound.

FIG. 1A shows a prior art structure comprising a substrate 1, copper layer 2, tungsten barrier layer 3, aluminum layer 4, and gold wiring layer 5. After all of the layers have been deposited, the structure will be annealed at a temperature sufficient to form an aluminum-gold intermetallic compound.

There is another hybrid scheme where aluminum can replace copper as the last interconnect level so that vias or trenches fill and bondpad formation can be combined into a single process step to simplify process flow and reduce costs. FIG. 1C shows a bondpad interconnect structure with a via formed therein. The structure comprises the topmost copper interconnect layer 100, a dielectric layer 102 having a via formed therein, a barrier layer 104, a passivation layer 106, and an aluminum layer 108 that fills the via. To fill the via with aluminum, the aluminum needs to be deposited or annealed post-deposition at a high temperature (i.e., greater than about 450° C.) to reflow the aluminum and fill the via. In this scheme, the aluminum 108 is in contact with the topmost copper interconnect layer 100 at the bottom of the via. A gold wiring layer can be placed on the aluminum layer 108 over the via.

Unfortunately, during the high-temperature reflow or annealing steps described above, the aluminum layer (layer 4 in FIG. 1A, layer 108 in FIG. 1C) will also react with the barrier layer so that the barrier will break down and an undesired intermetallic compound will be formed. FIGS. 1B and 1D show the structure that results after the reflow or annealing steps. As can be seen from FIGS. 1B and 1D, the aluminum layers 4, 108 have also reacted with the barrier layers 3, 104 to form intermetallic compound layers 3a, 110. The intermetallic compound layers 3a, 110 can have Kirkendall voids, which will degrade the thin barrier layer performance. Tantalum and tantalum nitride, when deposited by physical vapor deposition, produce polycrystalline films that will react with aluminum at the high temperatures used to reflow the aluminum (i.e., greater than about 250° C.) to form intermetallic compounds.

There is a need in the art for an effective barrier structure that prevents a copper-aluminum intermetallic compound from forming while also not reacting with the aluminum layer during subsequent reflow or annealing.

### SUMMARY OF THE INVENTION

The present invention generally comprises an aluminum bondpad and a method of its manufacture. In forming aluminum bondpads, a barrier layer is necessary between a copper layer and the aluminum layer. Additionally, a gold wiring layer is deposited on the aluminum layer and annealed at a high temperature to form an aluminum-gold intermetallic compound. Aluminum reacts with refractory metals such as tungsten, titanium, and tantalum at high temperatures. Therefore, during the post wire-bond annealing or aluminum reflow, the aluminum will react with the barrier and cause barrier failure. By providing an amorphous tungsten nitride barrier layer on a tungsten barrier layer, no aluminum-tungsten intermetallic compound will form, even at the higher temperatures required to fill the via in the aluminum hybrid scheme to form the aluminum bondpad.

In one embodiment, a method for forming an aluminum structure is disclosed. The method comprises positioning a substrate in a processing chamber, depositing a tungsten barrier layer over the substrate, depositing a tungsten nitride barrier layer on the tungsten barrier layer, and depositing an aluminum layer on the tungsten nitride barrier layer.

In another embodiment, an aluminum structure is disclosed. The aluminum structure comprises a substrate, a tungsten barrier layer over the substrate, a tungsten nitride barrier layer on the tungsten barrier layer, and an aluminum layer on the tungsten nitride barrier layer.

In another embodiment, a method for forming an aluminum structure is disclosed. The method comprises positioning a substrate with a copper layer thereon in a processing chamber, sputter depositing a tungsten barrier layer on the copper layer, sputter depositing a tungsten nitride barrier layer on the tungsten barrier layer, sputter depositing an aluminum layer on the tungsten nitride barrier layer, depositing a gold layer on the aluminum layer, and annealing at a temperature of greater than about 250° C.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic representation of a structure of the prior art prior to annealing.

FIG. 1B is a schematic representation of a structure of the prior art after annealing.

FIG. 1C is a schematic representation of a bondpad structure with a via of the prior art prior to reflowing the aluminum layer.

FIG. 1D is a schematic representation of a bondpad structure with a via of the prior art after reflowing the aluminum layer.

FIG. 2 is a flow chart showing the bi-layer barrier deposition process.

FIG. 3A is a schematic representation of a structure of the present invention prior to annealing.

FIG. 3B is a schematic representation of a structure of the present invention after annealing.

FIG. 3C is a schematic representation of a bondpad structure with a via of the present invention prior to reflowing the aluminum layer.

FIG. 3D is a schematic representation of a bondpad structure with a via of the present invention after reflowing the aluminum layer.

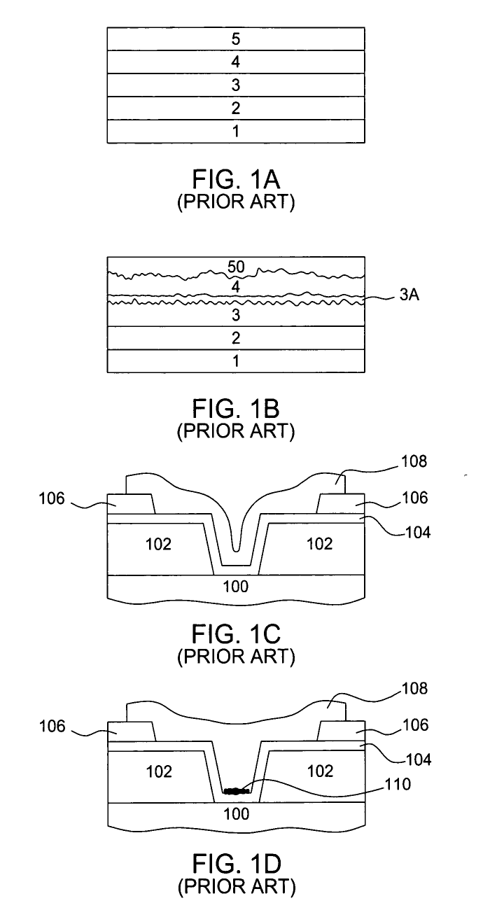

### DETAILED DESCRIPTION

The present invention generally comprises an aluminum bondpad and a method of its manufacture. Aluminum bondpad structures comprise a substrate, a copper interconnect layer, a barrier layer, an aluminum contact layer, and a gold wiring layer. The aluminum layer can be alloyed with other components such as copper, silicon, etc., in an amount of up to about 0.5 wt %.

The barrier layer prevents interdiffusion between the copper interconnect layer, the aluminum contact layer, and the gold wiring layer. An effective barrier layer should have minimal impact on the interconnect electrical resistance, provide effective adhesion to the surrounding passivation and the copper interconnect layer, stay intact when a strong down-force is exerted during thermosonic bonding, promote large aluminum grain growth, and orient large aluminum grain growth to reduce fast aluminum diffusion through aluminum grain boundaries.

One beneficial deposition method is physical vapor deposition (PVD). During a PVD process a target is electrically biased so that ions generated in a process region can bombard the target surface with sufficient energy to dislodge atoms from the target. The process of biasing a target to cause the generation of a plasma that causes ions to bombard and remove atoms from the target surface is commonly called sputtering. The sputtered atoms travel generally toward the substrate being sputter coated, and the sputtered atoms are deposited on the substrate. Alternatively, the atoms react with a gas in the plasma, for example, nitrogen, to reactively deposit a compound on the substrate. Reactive sputtering is often used to form thin barrier and nucleation layers of titanium nitride or tantalum nitride on the substrate.

The aluminum bondpad material layer needs to be close to about 1 micron thick in order to allow extensive aluminum-gold intermetallic compound growth during the annealing. The thick aluminum layer also provides a buffer to strong pressure exerted on the structure caused by bonding and die probing. The aluminum bondpad layer will be about 100 microns wide. The annealing is conducted at 250° C. or greater in order to cause the aluminum and gold to form an intermetallic compound. The annealing melts the gold layer through thermosonic energy. The intermetallic compound ensures aluminum to gold bonding reliability. It is the annealing that necessitates the barrier layer between the copper and aluminum. The barrier layer is to prevent the aluminum and copper from reacting during the annealing.

As discussed above, when tungsten is the barrier layer, the tungsten will react with the aluminum during the annealing to form an aluminum-tungsten intermetallic compound. The intermetallic compound at the aluminum-tungsten interface is undesirable because it will degrade the thin barrier layer performance and cause Kirkendall voids. The intermetallic compound will weaken the bondpad interfacial adhesion.

Tungsten nitride is another barrier material that is sometimes used. When tungsten nitride was used as the barrier material with an aluminum bondpad layer, it was found to not react with the aluminum bondpad layer and form an intermetallic compound during the annealing. In fact, the tungsten nitride will block copper interdiffusion with aluminum and gold, have a minimal impact on the interconnect electrical resistance, provide effective adhesion to the surrounding copper passivation and copper pad, stay intact during the thermosonic bonding, and orient and promote large aluminum grain growth to reduce fast gold diffusion through aluminum grain boundaries.

Another important feature of PVD tungsten nitride is its amorphous state. Other nitrides deposited by PVD tend to grow in polycrystalline form, which will not stop aluminum barrier intermetallic compound formation. As the purpose of the barrier layer is to prevent aluminum from interacting with any layers below the barrier layer, the amorphous state of the tungsten nitride layer is significant. Polycrystalline barrier layers will not stop aluminum diffusion through the barrier layer. If the aluminum diffuses through the barrier layer, then the aluminum can potentially react with the copper layer underneath. Additionally, the aluminum will react with the polycrystalline barrier layer at increased temperatures necessary to reflow the aluminum into the via. An amorphous tungsten nitride barrier layer prevents the aluminum from diffusing through the barrier layer, even at the temperatures necessary to reflow the aluminum into the via. By preventing the aluminum from diffusing through the barrier layer, the aluminum will not form an intermetallic compound with any layer below the barrier layer.

Tungsten nitride does have a major drawback. When a metal target is used for sputtering a metal nitride onto a wafer, the target is sputtered in the presence of nitrogen gas to produce the metal nitride in-situ during sputtering. The metal nitride will be deposited on the substrate, but also on any other exposed surfaces of the sputtering chamber. Inherent stress in the metal nitride film will case it to flake off. If the flaking occurs during the sputtering process, the substrate will be contaminated with particles of the meal nitride and damage the delicate circuitry in the semiconductor device. To control flaking, pasting is performed. Pasting involves periodically sputter depositing a layer of the metal over the metal nitride material deposited on the exposed process chamber portions to encapsulate the metal nitride and eliminate flaking. Of course, the pasting uses additional sputtering material, slows substrate throughput because the substrate must not be present during the pasting, and increases cost. Frequent pasting of tungsten is necessary to reduce particles during sputter deposition. Frequent pasting reduces target life, increases downtime, and increases costs. Therefore, tungsten nitride, while providing an effective barrier material, is not cost effective as a barrier material.

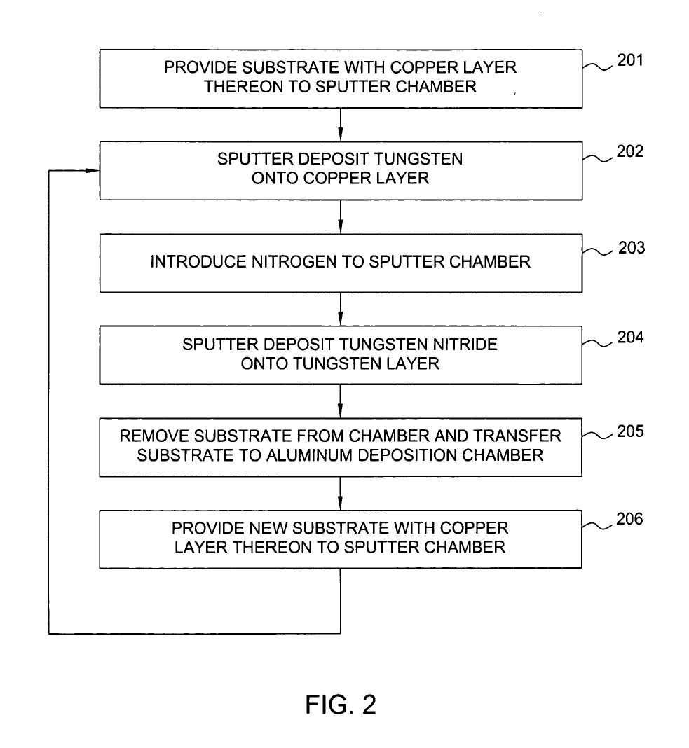

By using a double barrier layer of tungsten and tungsten nitride, pasting can be avoided. The pasting is avoided because both the tungsten layer and the tungsten nitride layer are deposited within the same chamber. Therefore, the “pasting” is occurring whenever the tungsten layer is being deposited onto a substrate. A separate pasting step is not necessary. FIG. 2 shows a flow chart for depositing the bi-layer barrier structure. In one embodiment, a first substrate with a copper layer thereon is placed into the chamber containing a tungsten sputtering target at step 201. A tungsten barrier layer is sputter deposited onto the substrate at step 202. Thereafter, nitrogen is introduced into the chamber at step 203 and a tungsten nitride layer is deposited over the tungsten barrier layer at step 204. Next, the substrate is removed at step 205 and a new substrate having a copper layer thereon is placed into the chamber at step 206. A tungsten layer is deposited onto the substrate at step 202. As the tungsten layer is deposited, tungsten is also deposited over the exposed surfaces of the chamber. Hence, the tungsten deposition for the second substrate pastes the tungsten nitride deposited when the tungsten nitride was deposited on the first substrate. Thus, the chamber downtime is reduced because there is no need to sputter the tungsten while no substrate is present as a separate pasting step. Thus, the target life is increased. Nitrogen is introduced into the chamber at step 203, and the tungsten nitride is sputtered to deposit a thin layer at step 204. The tungsten nitride deposited on the chamber is thin enough that no flaking should occur. Therefore, by using a bi-layer barrier of tungsten and tungsten nitride, substrate throughput can be increased and chamber downtime can be decreased because the pasting is an in-situ process when the bi-layer barrier structure of the invention is used.

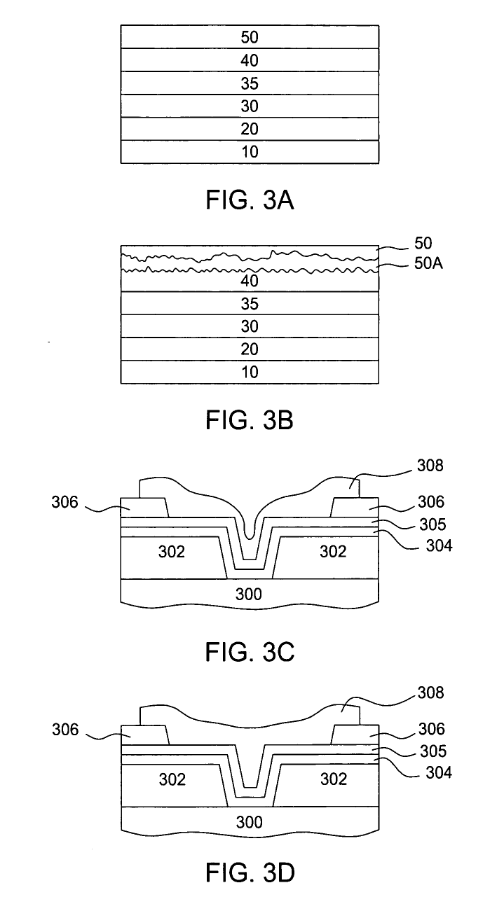

FIG. 3A shows an aluminum structure of the present invention. The structure is formed by providing a substrate 10 with a copper layer 20 thereon. On top of the copper layer 20, a tungsten barrier layer 30 is deposited. On top of the tungsten barrier layer 30, a tungsten nitride barrier layer 35 is deposited. On top of the tungsten nitride barrier layer 35, an aluminum layer 40 and a gold layer 50 are deposited.

FIG. 3B shows the structure of FIG. 3A after annealing. The annealing occurs at temperatures sufficient to cause a reaction between aluminum and gold to form an aluminum-gold intermetallic compound layer 50a between the gold layer 50 and the aluminum layer 40. As can be seen from FIG. 3B, there is no interaction between any layers other than the aluminum layer 40 and the gold layer 50. There is no interaction between the tungsten barrier layer 30 and the aluminum layer 40. There is no reaction between the tungsten nitride barrier layer 35 and the aluminum layer 40. There is no reaction between the aluminum layer 40 and the copper layer 20. Therefore, the barrier bi-layer performs its required function of preventing interdiffusion between the aluminum layer 40 and the copper layer 20 while also not reacting with the aluminum layer 40 during the annealing step.

FIGS. 3C and 3D show an aluminum bondpad structure using a tungsten/tungsten nitride barrier bilayer. The structure comprises a copper interconnect layer 300, dielectric layer 302 having a via, tungsten barrier layer 304, tungsten nitride barrier layer 305, passivation layer 306, and aluminum layer 308. The aluminum can be deposited by PVD or other deposition process, but the aluminum needs an elevated temperature (i.e., greater than about 250° C.) to become soft enough to flow completely into the via. FIG. 3C shows the structure before the aluminum is reflowed into the via. At elevated temperatures (i.e., greater than about 250° C.), aluminum will bond with copper or tungsten to form an intermetallic compound, but by having a tungsten nitride layer 305 over the tungsten layer 304, the aluminum will not react with either the tungsten or copper to form an intermetallic compound. Unlike other common refractory metals or their nitrides such as titanium, titanium nitride, tantalum, tantalum nitride, or tungsten, tungsten nitride will not react with the aluminum during the aluminum reflow. Copper, tantalum, titanium, and tungsten will normally react with aluminum at temperatures as low as 250° C. FIG. 3D shows the structure after the aluminum has reflowed into the via. As can be seen from FIG. 3D, the aluminum did not react with any of the layers below the aluminum layer 308.

It is important that the bi-layer barrier structure be deposited in the following order. First the tungsten layer is deposited and then the tungsten nitride layer is deposited within the same deposition chamber. If the order is reversed, then the tungsten layer is adjacent to the aluminum layer and all of the drawbacks associated with the tungsten barrier layer are present. In particular, the tungsten layer will react with the aluminum layer when the structure is annealed. Additionally, none of the benefits of tungsten nitride are present. In particular, the tungsten nitride will not be able to prevent interaction between the aluminum and the tungsten because the tungsten is already adjacent the aluminum layer.

A hybrid barrier bi-layer structure using two different metal materials would not overcome the pasting problem. For example, if the tungsten layer is replaced by another barrier material such as titanium or tantalum, then the first barrier layer of tantalum or titanium would be deposited in one chamber and the tungsten nitride would be deposited in a second chamber dedicated solely to depositing the tungsten nitride. Because no tungsten layer is ever deposited onto a substrate, the tungsten nitride on the exposed chamber surfaces would never be pasted during barrier layer deposition. Thus, the hybrid barrier bi-layer structure would have a reduced target life, increased downtime, and increased costs as compared to the tungsten and tungsten nitride barrier bi-layer structure.

The bi-layer barrier structure provides the benefits afforded by the single barrier structure of tungsten nitride. In particular, there is no copper interdiffusion with aluminum or gold, the aluminum grain growth is large so that gold fast diffusion through the aluminum grain boundaries is reduced, and the aluminum and gold can still form an aluminum-gold intermetallic compound. Additionally, at annealing temperatures necessary to create the aluminum-gold intermetallic compound layer, the tungsten nitride will not react with the aluminum.

The bi-layer does not provide the drawbacks of using the tungsten barrier layer and the tungsten nitride layers individually. In particular, because tungsten nitride is the top layer of the barrier bi-layer structure, there is no interaction between the aluminum layer and the tungsten layer because, as noted above, tungsten nitride does not react with the aluminum at the high annealing temperatures. Additionally, because the tungsten and tungsten nitride are both deposited within the same deposition chamber, there is no pasting problem because as the next substrate is processed after a tungsten nitride deposition, the tungsten layer will provide the necessary pasting to the sputtering chamber while the tungsten is deposited onto the next substrate.

The tungsten and tungsten nitride barrier bi-layer structure provides the benefits of an efficient barrier structure for aluminum bondpads. The tungsten and tungsten nitride barrier bi-layer structure has minimal impact on the interconnect electrical resistance, provides effective adhesion to the surrounding passivation and the copper interconnect layer, stays intact when a strong down-force is exerted during thermosonic bonding, promotes large aluminum grain growth, and orients large aluminum grain growth to reduce fast aluminum diffusion through aluminum grain boundaries. Additionally, no separate pasting step is required.

It should be understood that while the invention has been described with reference to PVD, the layers can be deposited by other equally effective methods known to one of ordinary skill in the art so long as the tungsten/tungsten nitride bi-layer barrier structure is formed and prevents formation of an aluminum intermetallic compound.

While the foregoing is directed to embodiments of the present invention, other and further embodiments of the invention may be devised without departing from the basic scope thereof, and the scope thereof is determined by the claims that follow.

We claim:

1. A method for forming an aluminum containing structure, comprising:
positioning a substrate in a processing chamber;
depositing a tungsten barrier layer over the substrate;
depositing a tungsten nitride barrier layer on the tungsten barrier layer; and
depositing an aluminum layer on the tungsten nitride barrier layer.

2. The method of claim 1, further comprising depositing a copper layer over the substrate before depositing the tungsten barrier layer.

3. The method of claim 1, further comprising depositing a gold wiring layer on the aluminum layer.

4. The method of claim 1, further comprising annealing the structure.

5. The method of claim 1, wherein the structure is an aluminum bondpad structure that comprises a via.

6. The method of claim 5, further comprising annealing the structure to a temperature greater than about 250° C. to reflow the aluminum into a via.

7. The method of claim 1, wherein the depositing is sputtering.

8. The method of claim 1, wherein the aluminum layer comprises up to about 0.5 wt % copper.

9. The method of claim 1, wherein the aluminum layer has a thickness greater than about 1 micron.

10. The method of claim 1, wherein a separate pasting step is not present.

11. The method of claim 1, wherein the tungsten barrier layer and the tungsten nitride barrier layer are formed with a single chamber.

12. An aluminum structure, comprising:
a substrate;
a tungsten barrier layer over the substrate;
a tungsten nitride barrier layer on the tungsten barrier layer; and
an aluminum layer on the tungsten nitride barrier layer.

13. The structure of claim 12, further comprising a copper layer between the substrate and the tungsten barrier layer.

14. The structure of claim 12, further comprising a gold layer on the aluminum layer.

15. The structure of claim 12, wherein the aluminum layer comprises up to about 0.5 wt % copper.

16. The structure of claim 12, wherein the aluminum layer has a thickness greater than about 1 micron.

17. The structure of claim 12, wherein no tungsten-aluminum intermetallic compound is present.

18. The structure of claim 12, wherein the structure is an aluminum bondpad structure that contains a via.

19. The structure of claim 12, wherein the tungsten nitride barrier layer is amorphous tungsten nitride.

20. A method for forming an aluminum bondpad structure, comprising:
positioning a substrate with a copper layer thereon in a processing chamber;
sputter depositing a tungsten barrier layer on the copper layer;
sputter depositing a tungsten nitride barrier layer on the tungsten barrier layer;
sputter depositing an aluminum layer on the tungsten nitride barrier layer;
depositing a gold layer on the aluminum layer; and
annealing at a temperature of greater than about 250° C.
